(19) United States
(12) Patent Application Publication
(10) Pub. No.: US 2007/0001551 A1
(43) Pub. Date: Jan. 4, 2007

(54) Sonic sensor and diaphragm

(75) Inventors: Makoto Izumi, Gifu-shi (JP); Seiji Suzuki, Ichinomiya-shi (JP)

Correspondence Address: MCDERMOTT WILL & EMERY LLP, 600 13TH STREET, N.W., WASHINGTON, DC, 20005-3096, US

(73) Assignee: Sanyo Electric Co., Ltd.

(21) Appl. No.: 11/474,380

(22) Filed: Jun. 26, 2006

(30) Foreign Application Priority Data
Jun. 30, 2005 (JP) JP2005-190856

(51) Int. Cl. H01L 41/00; H02N 2/00

(52) U.S. Cl. 310/328

(57) ABSTRACT

A sonic sensor capable of improving sensitivity while enabling downsizing is provided. This sonic sensor comprises an electrode plate and a diaphragm including a charge storage member opposed to the electrode plate at a prescribed distance and provided in a vibratory manner and a power generation member constituted of a piezoelectric substance capable of generating power upon vibration with the charge storage member. The charge storage member is so formed as to store charges supplied by the power generation member, for converting sound to an electrical signal on the basis of change in the capacitance between the diaphragm and the electrode plate.

### BACKGROUND OF THE INVENTION

1. Field of the Invention

The present invention relates to a sonic sensor and a diaphragm.

2. Description of the Background Art

A microphone (sonic sensor) sonically vibrating a diaphragm and extracting an electric signal corresponding to sound on the basis of change in the vibration is known in general (refer to Japanese Patent No. 3556676, for example).

FIG. 24 schematically illustrates the structure of a microphone disclosed in the aforementioned Japanese Patent No. 3556676. As shown in FIG. 24, the microphone disclosed in Japanese Patent No. 3556676 comprises a diaphragm 40 of SiN, an electrode 41a arranged on an end of the diaphragm 40 and another electrode 41b arranged oppositely to the electrode 41a at a prescribed interval. In this microphone, a booster circuit 42a included in a control circuit 42 applies a high voltage of at least 10 V between the electrodes 41a and 41b. When the diaphragm 40 is sonically vibrated, the electrode 41a arranged on the end of the diaphragm 40 is also vibrated due to this vibration of the diaphragm 40. Thus, the distance between the electrodes 41a and 41b changes to change the capacitance of a capacitor formed by the electrodes 41a and 41b. Consequently, the potential of the electrode 41b changes, so that an amplification circuit 42b amplifies the potential change and outputs the same as an electric signal corresponding to sound.

A microphone comprising a diaphragm constituted of a piezoelectric substance is also known as another exemplary sonic sensor extracting an electric signal corresponding to sound through a diaphragm. As shown in FIG. 25, this microphone comprises a diaphragm 45 constituted of a piezoelectric substance, a pair of electrodes 46a and 46b provided to hold the front and back surfaces of the diaphragm 45 therebetween, an amplification circuit 47 for amplifying a voltage converted from a current by a high resistor 48 and the high resistor 48 for obtaining a potential of the electrode 46a with respect to the ground potential (0 V) by converting the current to the voltage (potential) while preventing current loss. First ends of the high resistor 48 and the amplification circuit 47 are grounded. When the diaphragm 45 constituted of the piezoelectric substance is sonically vibrated, the diaphragm 45 and the electrodes 46a and 46b are deformed as shown in FIG. 26. When the diaphragm 45 is deformed, negative and positive charges are generated on the upper and lower surfaces of the diaphragm 45 respectively by a piezoelectric effect. Thus, a current flows to the high resistor 48, which in turn converts this current to a voltage. The amplification circuit 47 amplifies this voltage, thereby converting sound to an electric signal and outputting the same.

In the microphone according to Japanese Patent No. 3556676 shown in FIG. 24, however, the diaphragm 40 of SiN cannot store charges. In order to cause potential difference between the electrodes 41a and 41b and extract change of the capacitance as an electric signal, therefore, a high voltage must be regularly applied to the electrode 41a. Therefore, the control circuit 42, which must be provided with the booster circuit 42a having a large circuit scale, is inevitably increased in size, disadvantageously resulting in size increase of the microphone. In the conventional microphone comprising the diaphragm 45 constituted of the piezoelectric substance shown in FIGS. 25 and 26 the voltage generated by the piezoelectric effect resulting from single vibration is so small that the electric signal converted from the sound is weak. Consequently, sensitivity of the microphone is disadvantageously reduced. When the sensitivity of the microphone is improved by increasing the area of the diaphragm 45 constituted of the piezoelectric substance, the microphone is disadvantageously increased in size.

### SUMMARY OF THE INVENTION

The present invention has been proposed in order to solve the aforementioned problems, and an object of the present invention is to provide a sonic sensor and a diaphragm therefor, which can improve sensitivity of the sonic sensor such as a microphone while enabling downsizing thereof.

A sonic sensor according to a first aspect of the present invention comprises an electrode plate and a diaphragm including a charge storage member opposed to the electrode plate at a prescribed distance and provided in a vibratory manner and a power generation member constituted of a piezoelectric substance capable of generating power upon vibration with the charge storage member, while the charge storage member is so formed as to store charges supplied by the power generation member, for converting sound to an electrical signal on the basis of change in the capacitance between the diaphragm and the electrode plate.

In the sonic sensor according to the first aspect of the present invention, the diaphragm is provided with the vibratory charge storage member so formed as to store charges and the power generation member capable of generating power upon vibration with the charge storage member so that the power generation member constituted of the piezoelectric substance is also vibrated when the charge storage member is sonically vibrated, whereby the charge storage member stores charges generated by the power generation member to cause potential difference between the electrode plate and the diaphragm. When the diaphragm is vibrated in the state causing potential difference between the same and the electrode plate, the distance between the electrode plate and the diaphragm so changes as to change the capacitance of a capacitor formed by the electrode plate and the diaphragm as well as the potential of the electrode plate. The sonic sensor can convert sound or the like to an electrical signal by outputting the potential change as an electric signal. Further, the sonic sensor, capable of storing charges in the charge storage member by vibrating the power generation member constituted of the piezoelectric substance, requires no booster circuit or the like for applying a voltage to the diaphragm. Thus, a control circuit of the sonic sensor can be downsized, thereby downsizing the sonic sensor. In addition, the power generation member repetitively generates power due to the vibration, whereby the charge storage member can store a large quantity of charges. Thus, large potential difference can be caused between the electrode plate and the diaphragm including the charge storage member, thereby increasing potential change of the electrode plate corresponding to change of the capacitance of the capacitor formed by the electrode plate and the diaphragm. Therefore, sensitivity of the sonic sensor can be improved without increasing the size of the diaphragm. According to the first aspect, therefore, the sonic sensor can be improved in sensitivity and downsized.

In the aforementioned sonic sensor according to the first aspect, a rectifier suppressing outflow of charges is preferably electrically connected to the power generation member. According to this structure, the flow of charges generated by the power generation member can be unidirectionally fixed toward the charge storage member while outflow of the charges stored in the charge storage member can be suppressed, whereby the charge storage member hardly loses the charges supplied from the power generation member. Thus, the sonic sensor can efficiently store the charges in the charge storage member.

In the aforementioned sonic sensor according to the first aspect, the power generation member constituted of the piezoelectric substance is preferably arranged on the outer periphery of the charge storage member. According to this structure, the sonic sensor can supply charges generated by the power generation member to the charge storage member from the outer periphery thereof while ensuring vibrational performance of a maximumly vibrated portion of the charge storage member by arranging the power generation member on the outer periphery of the charge storage member having a circular shape when the circular charge storage member is maximumly vibrated on the central portion, for example.

In the aforementioned sonic sensor having the power generation member arranged on the outer periphery of the charge storage member, the power generation member constituted of the piezoelectric substance preferably includes a power generation film constituted of the piezoelectric substance, and is preferably so formed as to generate either positive charges or negative charges on the outer periphery of the power generation film in plan view and to generate either negative charges or positive charges on the inner periphery of the power generation film, on which the charge storage member is located, in plan view. According to this structure, external negative charges are attracted by positive charges generated on the outer periphery of the power generation film to flow into the sonic sensor when the power generation member is so formed as to generate positive charges on the inner periphery of the power generation film and to generate negative charges on the inner periphery of the power generation film. These negative charges flow from the outer periphery toward the inner periphery of the power generation film, whereby the charge storage member can store the negative charges. When the power generation member is so formed as to generate negative charges on the outer periphery of the power generation film and to generate positive charges on the inner periphery of the power generation film, on the other hand, external positive charges are attracted by negative charges generated on the outer periphery of the power generation film, to flow into the sonic sensor. These positive charges flow from the outer periphery toward the inner periphery of the power generation film, whereby the charge storage member stores the positive charges. Thus, the sonic sensor can unidirectionally fix the flow of positive and negative charges generated by the power generation film, thereby more efficiently storing the charges in the charge storage member.

In this case, the power generation film constituted of the piezoelectric substance may be so polarized as to generate positive charges on the outer periphery of the power generation film and to generate negative charges on the inner periphery of the power generation film.

In the aforementioned sonic sensor having the power generation member arranged on the outer periphery of the charge storage member, the power generation member constituted of the piezoelectric substance is preferably so formed as to enclose the outer periphery of the charge storage member in plan view. According to this structure, the power generation member can supply charges to the charge storage member from the overall outer periphery of the charge storage member, thereby supplying a larger quantity of charges to the charge storage member.

In the aforementioned sonic sensor having the power generation member enclosing the outer periphery of the charge storage member, the charge storage member is preferably circularly formed in plan view, and the power generation member is preferably so annularly formed as to enclose the circular charge storage member. According to this structure, the power generation member can easily enclose the charge storage member.

In the aforementioned sonic sensor according to the first aspect, the charge storage member may include a conductive semiconductor film.

In the aforementioned sonic sensor according to the first aspect, the charge storage member and the power generation member are preferably so formed as to at least partially overlap with each other. According to this structure, the power generation member can be easily mounted on the charge storage member.

A diaphragm according to a second aspect of the present invention comprises a charge storage member opposed to an electrode plate at a prescribed distance and provided in a vibratory manner and a power generation member constituted of a piezoelectric substance capable of generating power upon vibration with the charge storage member, while the charge storage member is so formed as to store charges supplied by the power generation member.

As hereinabove described, the diaphragm according to the second aspect of the present invention is provided with the vibratory charge storage member so formed as to store charges and the power generation member capable of generating power upon vibration with the charge storage member so that the power generation member constituted of the piezoelectric substance is also vibrated when the charge storage member is sonically vibrated, whereby the charge storage member stores charges generated by the power generation member to cause potential difference between the electrode plate and the diaphragm. When the diaphragm is vibrated in the state causing potential difference between the same and the electrode plate, the distance between the electrode plate and the diaphragm so changes as to change the capacitance of a capacitor formed by the electrode plate and the diaphragm as well as the potential of the electrode plate. The diaphragm can convert sound or the like to an electrical signal by outputting the potential change as an electric signal. Further, the diaphragm, capable of storing charges in the charge storage member by vibrating the power generation member constituted of the piezoelectric substance, requires no booster circuit or the like for applying a voltage thereto. Thus, a control circuit of the diaphragm can be downsized, thereby downsizing a sonic apparatus such as a sonic sensor to which the diaphragm is applied. In addition, the power generation member repetitively generates power due to the vibration, whereby the charge storage member can store a large quantity of charges. Thus, large potential difference can be caused between the electrode plate and the diaphragm including the charge storage member, thereby increasing potential change of the electrode plate corresponding to change of the capacitance of the capacitor formed by the electrode plate and the diaphragm. Thus, the extracted electric signal can be intensified. Consequently, sensitivity of a sonic sensor or the like can be improved without increasing the size of the diaphragm.

In the aforementioned diaphragm according to the second aspect, a rectifier suppressing outflow of charges is preferably electrically connected to the power generation member. According to this structure, the flow of charges generated by the power generation member can be unidirectionally fixed toward the charge storage member while outflow of the charges stored in the charge storage member can be suppressed, whereby the charge storage member hardly loses the charges supplied from the power generation member. Thus, the diaphragm can efficiently store the charges in the charge storage member.

In the aforementioned diaphragm according to the second aspect, the power generation member constituted of the piezoelectric substance is preferably arranged on the outer periphery of the charge storage member. According to this structure, the diaphragm can supply charges generated by the power generation member to the charge storage member from the outer periphery thereof while ensuring vibrational performance of a maximumly vibrated portion of the charge storage member by arranging the power generation member on the outer periphery of the charge storage member having a circular shape when the circular charge storage member is maximumly vibrated on the central portion, for example.

In the aforementioned diaphragm having the power generation member arranged on the outer periphery of the charge storage member, the power generation member constituted of the piezoelectric substance preferably includes a power generation film constituted of the piezoelectric substance, and is preferably so formed as to generate either positive charges or negative charges on the outer periphery of the power generation film in plan view and to generate either negative charges or positive charges on the inner periphery of the power generation film, on which the charge storage member is located, in plan view. According to this structure, external negative charges are attracted by positive charges generated on the outer periphery of the power generation film to flow into the diaphragm when the power generation member is so formed as to generate positive charges on the inner periphery of the power generation film and to generate negative charges on the inner periphery of the power generation film. These negative charges flow from the outer periphery toward the inner periphery of the power generation film, whereby the charge storage member can store the negative charges. When the power generation member is so formed as to generate negative charges on the outer periphery of the power generation film and to generate positive charges on the inner periphery of the power generation film, on the other hand, external positive charges are attracted by negative charges generated on the outer periphery of the power generation film, to flow into the diaphragm. These positive charges flow from the outer periphery toward the inner periphery of the power generation film, whereby the charge storage member stores the positive charges. Thus, the diaphragm can unidirectionally fix the flow of positive and negative charges generated by the power generation film, thereby more efficiently storing the charges in the charge storage member.

In this case, the power generation film constituted of the piezoelectric substance may be so polarized as to generate positive charges on the outer periphery of the power generation film and to generate negative charges on the inner periphery of the power generation film.

In the aforementioned diaphragm having the power generation member set on the outer periphery of the charge storage member, the power generation member constituted of the piezoelectric substance is preferably so formed as to enclose the outer periphery of the charge storage member in plan view. According to this structure, the power generation member can supply charges to the charge storage member from the overall outer periphery of the charge storage member, thereby supplying a larger quantity of charges to the charge storage member.

In the aforementioned diaphragm having the power generation member enclosing the outer periphery of the charge storage member, the charge storage member is preferably circularly formed in plan view, and the power generation member is preferably so annularly formed as to enclose the circular charge storage member. According to this structure, the power generation member can easily enclose the charge storage member.

In the aforementioned diaphragm according to the second aspect, the charge storage member may include a conductive semiconductor film.

In the aforementioned diaphragm according to the second aspect, the charge storage member and the power generation member are preferably so formed as to at least partially overlap with each other. According to this structure, the power generation member can be easily mounted on the charge storage member.

In the aforementioned diaphragm according to the second aspect, the electrode plate may include a plurality of sonic holes, and the diaphragm may be applied to an audio.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a sectional view showing the structure of a microphone including a diaphragm according to an embodiment of the present invention;

FIG. 2 is a plan view of the diaphragm and a back plate of the microphone shown in FIG. 1;

FIG. 3 is a plan view of the diaphragm of the microphone shown in FIG. 1;

FIGS. 4 to 13 are sectional views for illustrating a fabrication process for the diaphragm according to the embodiment shown in FIG. 1 and the periphery thereof;

FIG. 14 is a plan view for illustrating the circuit structure and operations of the microphone according to the embodiment shown in FIG. 1;

FIG. 15 is a sectional view for illustrating the circuit structure and the operations of the microphone according to the embodiment shown in FIG. 1;

FIG. 16 is a plan view for illustrating the circuit structure and the operations of the microphone according to the embodiment shown in FIG. 1;

FIG. 17 is a sectional view for illustrating the circuit structure and the operations of the microphone according to the embodiment shown in FIG. 1;

FIG. 18 is a plan view for illustrating the circuit structure and the operations of the microphone according to the embodiment shown in FIG. 1;

FIG. 19 is a sectional view for illustrating the circuit structure and the operations of the microphone according to the embodiment shown in FIG. 1;

FIG. 20 is a plan view for illustrating the circuit structure and the operations of the microphone according to the embodiment shown in FIG. 1;

FIGS. 21 and 22 are sectional views for illustrating the circuit structure and the operations of the microphone according to the embodiment shown in FIG. 1;

FIG. 23 is a sectional view of a diaphragm provided on a microphone according to a modification of the embodiment of the present invention and the periphery thereof;

FIG. 24 is a schematic block diagram illustrating a conventional diaphragm of SiN; and

FIGS. 25 and 26 are schematic block diagrams illustrating another conventional diaphragm constituted of a piezoelectric substance.

### DESCRIPTION OF THE PREFERRED EMBODIMENTS

An embodiment of the present invention is now described with reference to the drawings. In the following description, the present invention is applied to a microphone, which is a kind of sonic sensor.

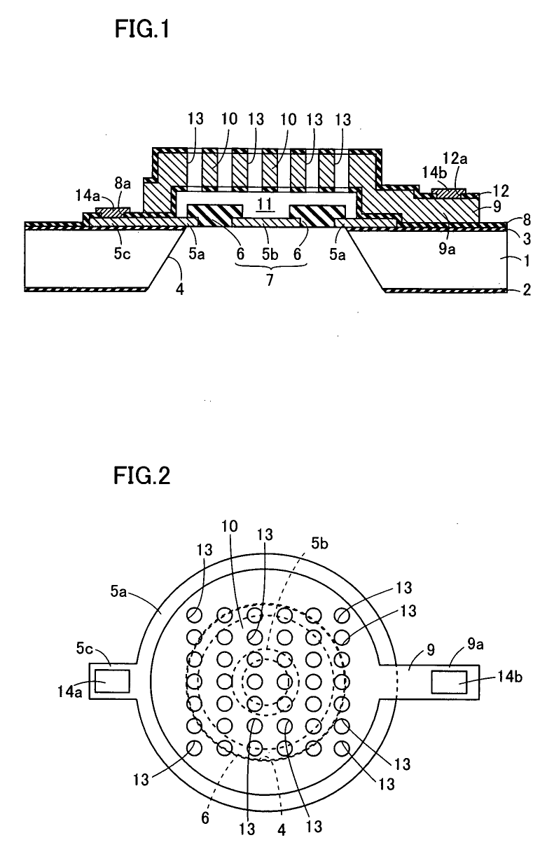

The structure of a microphone including a diaphragm according to the embodiment of the present invention is described with reference to FIGS. 1 to 3.

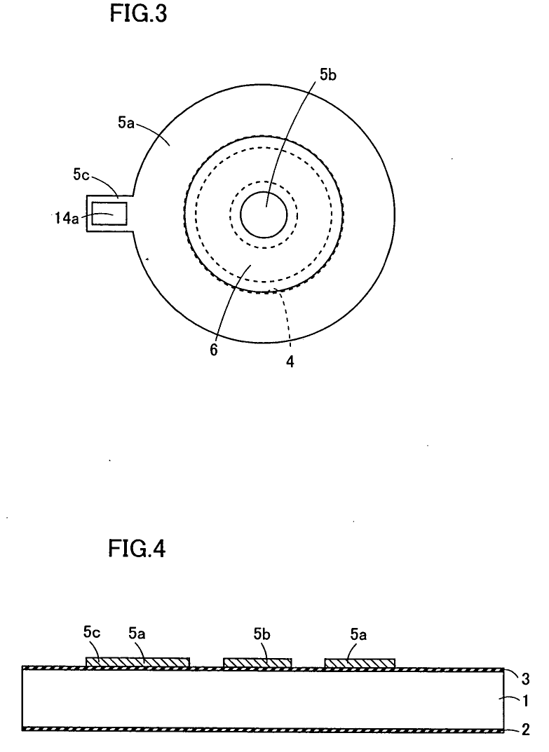

In the microphone according to this embodiment, SiO₂ layers 2 and 3 each having a thickness of about 250 nm are formed on the back and front surfaces of a silicon substrate 1 respectively, as shown in FIG. 1. A partially conical (head-trimmed conical) opening 4 is formed in a region for forming a diaphragm 7 described later, to pass through the silicon substrate 1 and the SiO₂ layers 2 and 3. This opening 4 functions as an air passage when the microphone receives sound. A polysilicon layer 5a having a thickness of about 1 μm is partially formed on the SiO₂ layer 3 and the opening 4. This polysilicon layer 5a is annularly formed in plan view as shown in FIGS. 2 and 3, and doped with an n-type impurity (phosphorus (P)) to have conductivity. A discoidal polysilicon layer 5b having an outer diameter of about 0.6 mm in plan view is formed around the center of the upper end of the opening 4. This polysilicon layer 5b is also doped with an n-type impurity (phosphorus (P)) to have conductivity, and capable of storing charges. The polysilicon layer 5b is an example of the “charge storage member” or the “semiconductor film” in the present invention. A power generation film 6 having a thickness of about 1 μm is so formed as to enclose the outer periphery of the polysilicon layer 5b. This power generation film 6 is constituted of a heat-resistant piezoelectric substance (PbTiO₃ (Curie temperature: about 490° C.), for example) having a high Curie temperature, and provided in the form of a ring having an outer diameter of about 1 mm and an inner diameter of about 0.5 mm in plan view. Further, the power generation film 6 is in contact with the polysilicon layer 5, so that the polysilicon layer 5 encloses the outer periphery of the power generation film 6. The inner and outer peripheries of the power generation film 6 are located on an upper surface portion of the polysilicon layer 5b around the outer periphery thereof and an upper surface portion of the polysilicon layer 5a around the inner periphery thereof respectively. The power generation film 6 has a function of generating charges by a piezoelectric effect through sonic vibration and supplying the charges to the polysilicon layer 5b. The polysilicon layer 5b and the power generation film 6 constitute the diaphragm 7. The power generation film 6 is an example of the “power generation member” in the present invention.

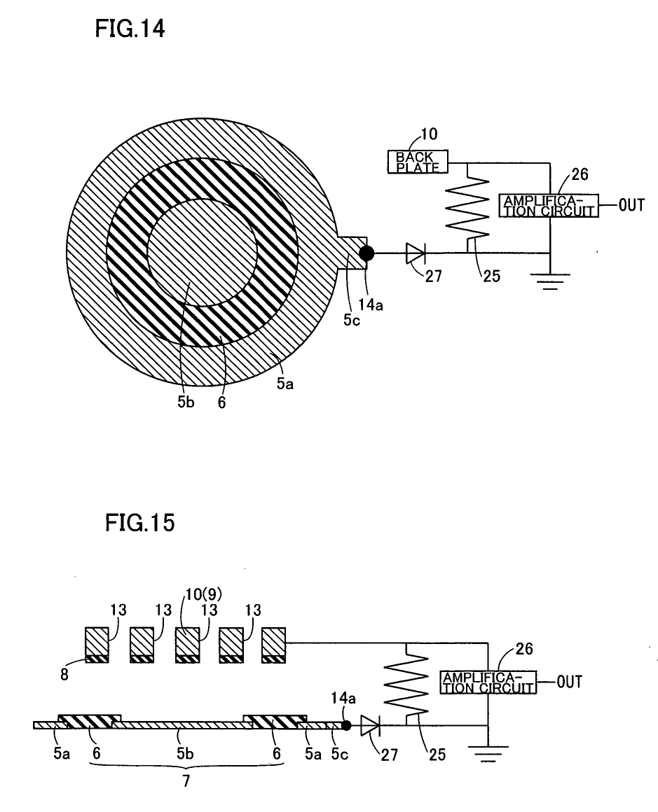

An SiN layer 8 having a thickness of about 100 nm is partially formed on the upper surfaces of the polysilicon layer 5a and the SiO₂ layer 3. A polysilicon layer 9 having a thickness of about 3 μm is formed on the SiN layer 8. This polysilicon layer 9 is doped with an n-type impurity (phosphorus (P)), to have conductivity. A portion of the polysilicon layer 9 opposed to the diaphragm 7 functions as a back plate 10. The back plate 10 is an example of the “electrode plate” in the present invention. A space 11 for insulating the back plate 10 and the diaphragm 7 from each other is formed between the SiN layer 8 and the polysilicon layers 5a and 5b and the power generation film 7. The distance between the back plate 10 and the diaphragm 7 in this space 11 is about 3 μm to about 5 μm. Another SiN layer 12 having a thickness of about 100 nm is formed on the polysilicon layer 9. A plurality of circular sonic holes 13 (see FIG. 2) externally linked to the space 11 are formed in the SiN layers 8 and 12 and the back plate 10. These sonic holes 13 function as air passages when the microphone receives sound. Electrodes 14a and 14b of aluminum (Al) are formed on contact areas 5c and 9a of the polysilicon layers 5a and 9 respectively. The electrode 14a is connected to the polysilicon layer 5b through the polysilicon layer 5a and the power generation film 7. A diode 27 (see FIG. 14) formed by a Schottky diode or a p-n junction diode is connected to the electrode 14a, for preventing outflow of charges stored in the polysilicon layer 5b. The diode 27 is an example of the “rectifier” in the present invention.

A fabrication process for the diaphragm according to the embodiment of the present invention and the periphery thereof is now described with reference to FIGS. 1 and 4 to 13.

First, the back and front surfaces of the silicon substrate 1 are polished, for thereafter forming the SiO₂ layers 2 and 3 each having the thickness of about 250 nm thereon by thermal oxidation respectively, as shown in FIG. 4. Thereafter a polysilicon layer (not shown) having a thickness of about 1 μm is formed by CVD with raw material gas of monosilane or dichlorosilane, and phosphorus (P) employed as the n-type impurity is thereafter ion-implanted into this polysilicon layer. Thereafter the polysilicon layer is patterned by photolithography and etching, thereby forming the polysilicon layers 5a and 5b, which are annular and discoidal in plan view respectively. The polysilicon layer 5a is so patterned as to have the contact area 5c.

Then, a piezoelectric layer (not shown) of PbTiO₃ is formed on the overall surface by a sol-gel process, and thereafter patterned by photolithography and dry etching with argon, oxygen and CF₄, thereby forming the annular power generation film 6 of PbTiO₃ having the thickness of about 1 μm, the outer diameter of about 1 mm and the inner diameter of about 0.5 mm, as shown in FIG. 5.

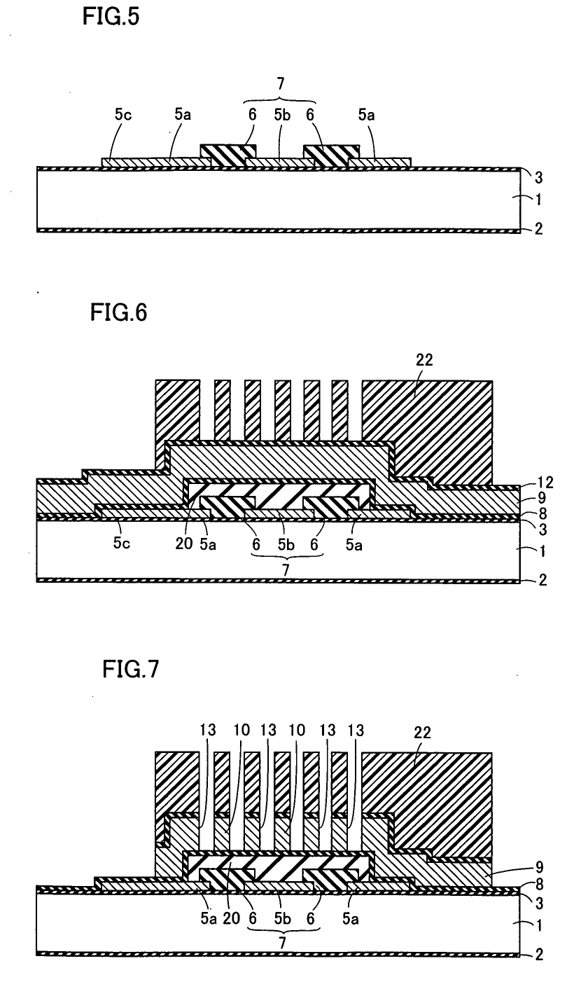

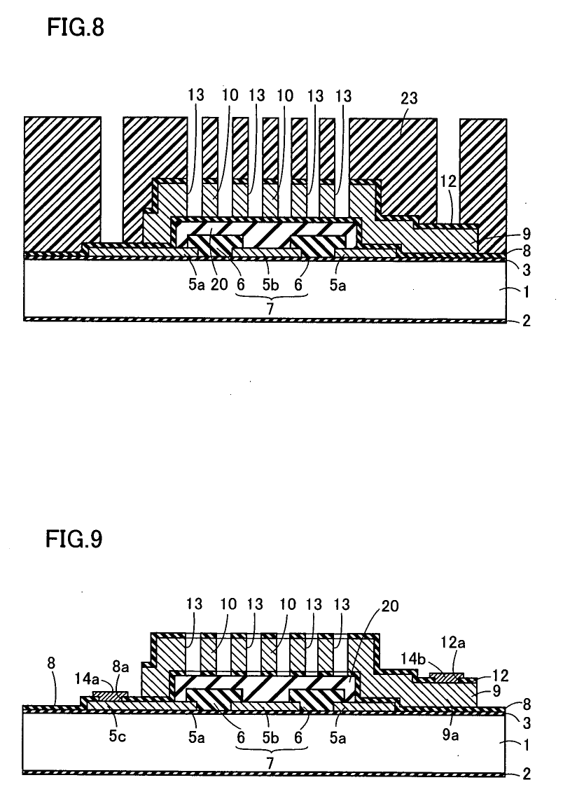

As shown in FIG. 6, an SiO₂ layer 20 having a thickness of about 3 μm to about 5 μm is formed by CVD to cover the overall surface, and thereafter patterned by photolithography and dry etching. Thus, the SiO₂ layer 20 is so patterned as to form the space 11 (see FIG. 1). Then, the SiN layer 8 having the thickness of about 100 nm is formed by CVD with a gas mixture of monosilane and ammonia or dichlorosilane and ammonia at a film forming temperature of about 300° C. to about 600° C., to cover the overall surface. Thereafter the polysilicon layer 9 having the thickness of about 3 μm is formed on the overall surface of the SiN layer 8 by CVD with monosilane gas or dichlorosilane gas, and phosphorus (P) employed as the n-type impurity is thereafter ion-implanted into this polysilicon layer 9. Thereafter the SiN layer 12 having the thickness of about 100 nm is formed on the overall surface of the polysilicon layer 9 by CVD with a gas mixture of monosilane and ammonia or dichlorosilane and ammonia at a film forming temperature of about 300° C. to about 600° C. Thereafter resist films 22 are formed by photolithography. The resist films 22 are employed as masks for etching the SiN layer 12 while setting argon, oxygen and CF₄ to prescribed mixing ratios suitable for etching SiN and thereafter etching the polysilicon layer 9 while changing the mixing ratios of argon, oxygen and CF₄ to levels suitable for etching polysilicon, thereby forming a shape shown in FIG. 7. Thereafter the resist films 22 are removed. As shown in FIG. 8, resist films 23 are formed on regions of the SiN layers 8 and 12 excluding those for forming the electrodes 14a and 14b and the sonic holes 13. The resist films 23 are employed as masks for etching the SiN layers 8 and 12 while returning the mixing ratios of argon, oxygen and CF₄ to the levels suitable for etching SiN, thereby forming the plurality of sonic holes 13 and the contact holes 8a and 12a. Thereafter the resist films 23 are removed.

As shown in FIG. 9, the electrodes 14a and 14b of Al are formed by vapor deposition, to be connected to the contact areas 5c and 9a of the polysilicon layers 5a and 9 through the contact holes 8a and 12a respectively.

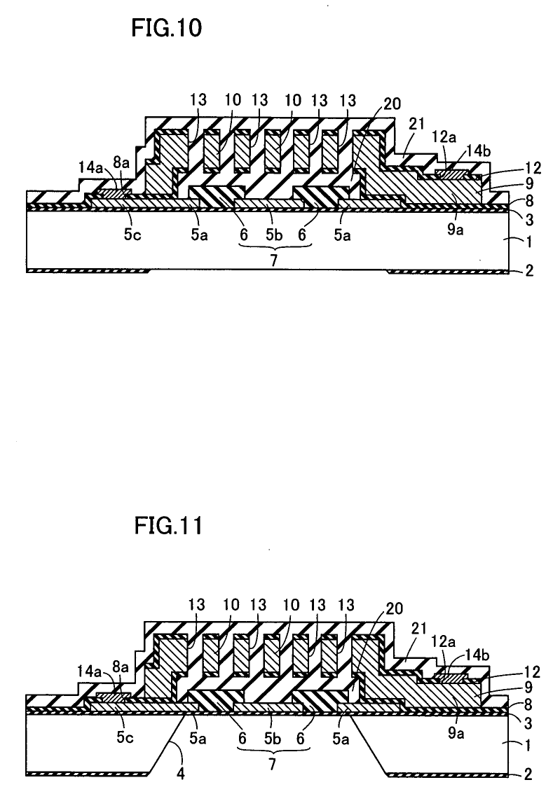

As shown in FIG. 10, an SiO₂ layer 21 serving as a protective film is so formed as to cover the overall upper surface and to fill up the sonic holes 13. Thereafter a portion of the SiO₂ layer 2 provided on the back surface of the silicon substrate 1 for forming the opening 4 (see FIG. 1) is removed by photolithography and etching.

As shown in FIG. 11, the SiO₂ layer 2 is employed as a mask for removing a portion of the silicon substrate 1 for forming the opening 4 by anisotropic wet etching with an aqueous solution of tetramethylammonium hydroxide (TMAH) or potassium hydroxide, thereby forming the partially conical (head-trimmed conical) opening 4.

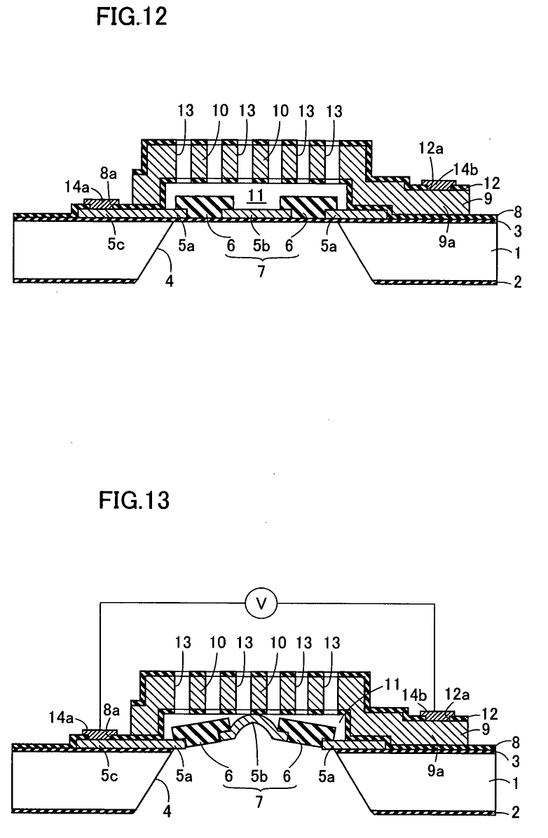

As shown in FIG. 12, the SiO₂ layer 21 serving as the protective film and the SiO₂ layer 20 for forming the space 11 are removed by wet etching with hydrofluoric acid. Thereafter a portion of the SiO₂ layer 3 formed under the diaphragm 7 is removed by wet etching with hydrofluoric acid.

As shown in FIG. 13, the power generation film 6 is so polarized as to unidirectionally feed charges generated by the power generation film 6. More specifically, the power generation film 6 is first heated to a temperature level close to the Curie temperature (about 490° C.) of the piezoelectric substance (PbTiO₃) constituting the power generation film 6. In this state, a voltage is applied between the electrodes 14a and 14b so that the potential of the electrode 14a is higher than that of the electrode 14b, thereby reducing the potential of the central portion of the polysilicon layer 5b connected to the electrode 14a through the polysilicon layer 5a and the power generation film 6 below that of the back plate 10. In order to substantially equalize the potentials of the back plate 10 and the polysilicon layer 5b to each other, the voltage applied between the electrodes 14a and 14b is increased so that a portion of the SiN layer 8 located under the back plate 10 and the polysilicon layer 5b come into contact with each other by electrostatic force. Thus, the back plate 10 and the SiN layer 8 come into contact with each other to reach the same potential level, for maintaining a state of applying a voltage substantially identical to that applied between the electrodes 14a and 14b to the power generation film 6 until the power generation film 6 is cooled. Thus, the power generation film 6 constituted of the piezoelectric substance is so polarized as to generate positive charges on the outer periphery of the power generation film 6 and to generate negative charges on the inner periphery of the power generation film 6, on which the polysilicon layer 5b is located.

FIGS. 14 to 22 are plan views and sectional views for illustrating the circuit structure and operations of the microphone according to this embodiment. The circuit structure of the microphone according to this embodiment is now described with reference to FIGS. 14 and 15.

As shown in FIGS. 14 and 15, a high resistor 25 for obtaining the potential of the back plate 10 with respect to the ground potential (0 V) by converting a current to a voltage (potential) while preventing current loss and an amplification circuit 26 for amplifying the voltage converted from the current by the high resistor 25 are parallelly connected between the diaphragm 7 and the back plate 10. A first end of the high resistor 25 and a first input end of the amplification circuit 26 are grounded. A first terminal of the diode 27 is connected to the diaphragm 7. The diode is provided as to feed the current only in a direction for supplying negative charges to the polysilicon layer 5b, thereby preventing outflow of negative charges stored in the polysilicon layer 5b. A second terminal of the diode 27 is grounded.

The operations of the microphone according to this embodiment are now described with reference to FIGS. 14 to 22. When the microphone receives no sound, the diaphragm 7 remains unvibrational, as shown in FIGS. 14 and 15. Therefore, no stress acts on the power generation film 6 constituted of the piezoelectric substance (PbTiO₃), whereby the power generation film 6 causes no potential difference.

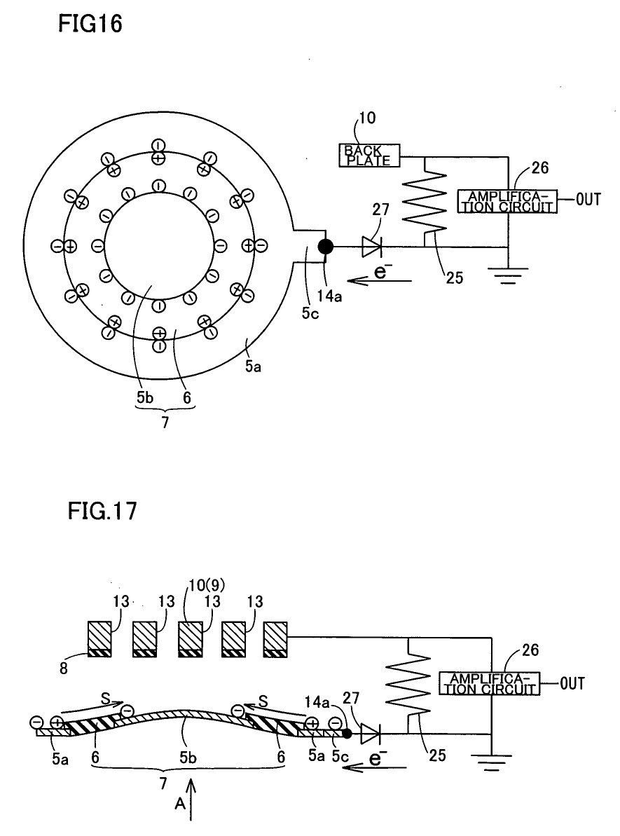

When the microphone receives sound along arrow A as shown in FIGS. 16 and 17, on the other hand, the diaphragm 7 is vibrated. Thus, tensile stress S acts on the power generation film 6 constituted of the piezoelectric substance, so that the power generation film 6 generates power due to change of the quantity of polarization. In this state of the polarized power generation film 6 constituted of the piezoelectric substance, positive charges concentrate on the outer periphery (closer to the polysilicon layer 5a) of the power generation film 6 while negative charges concentrate on the inner periphery (closer to the polysilicon layer 5b) of the power generation film 6. Negative charges are attracted by the positive charges generated on the outer periphery of the power generation film 6, to flow toward the polysilicon layer 5b from the grounded second terminal of the diode 27.

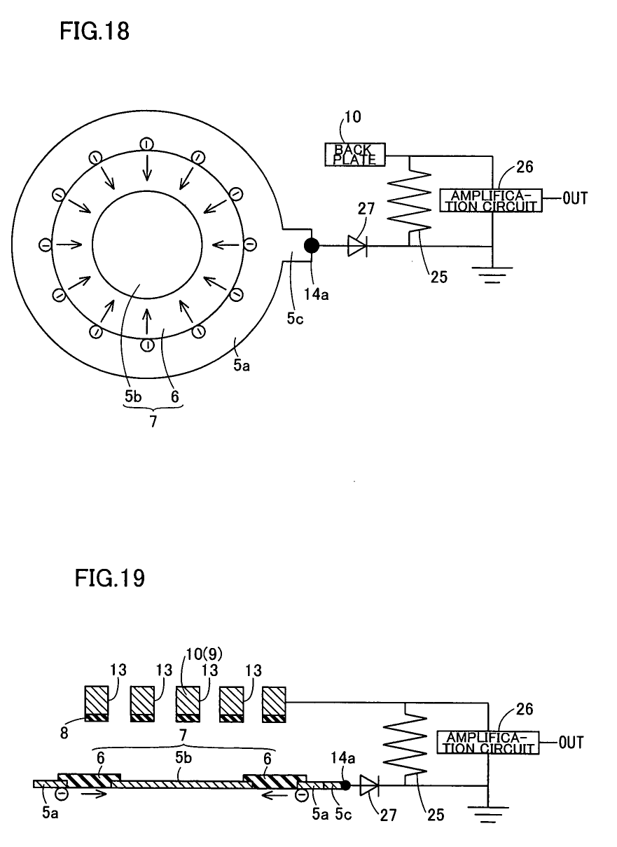

When the diaphragm 7 is flattened as shown in FIGS. 18 and 19, no charges concentrate on the outer periphery or the inner periphery of the power generation film 6 since no stress acts on the power generation film 6. However, negative charges stored in the polysilicon layer 5a cannot flow out from the polysilicon layer 5a due to the diode 27. Therefore, the potential of the polysilicon layer 5a is reduced due to the negative charges stored therein. Thus, the negative charges stored in the polysilicon layer 5a flow toward the polysilicon layer 5b having the higher potential through the power generation film 6 having resistivity (10⁹ Ω·m, for example) smaller than that of an insulator.

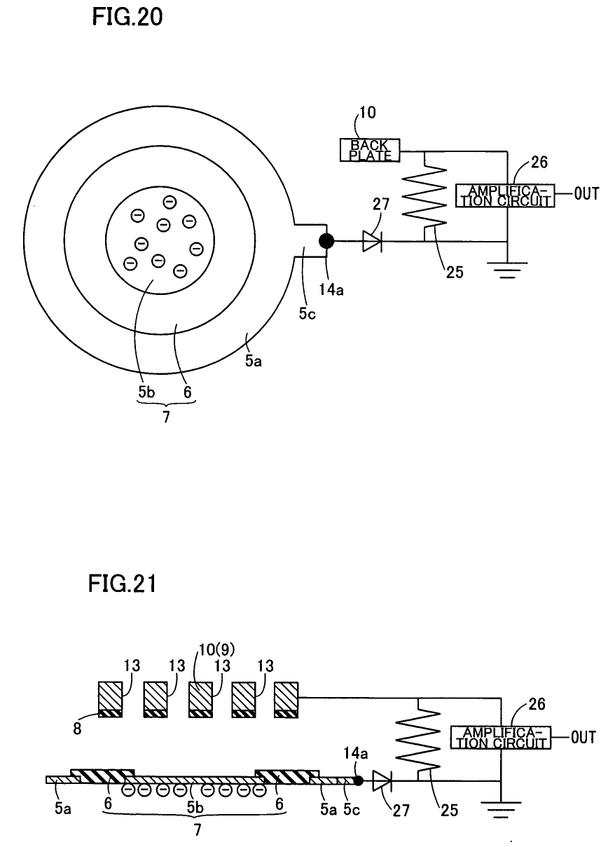

Thus, the polysilicon layer 5b stores the negative charges as shown in FIGS. 20 and 21. Thereafter the diaphragm 7 is so repetitively vibrated that the polysilicon layer 5b gradually stores negative charges up to a limit voltage withstandable for the diode 27. Thus, large potential difference (30 V, for example) can be caused between the back plate 10 and the polysilicon layer 5b.

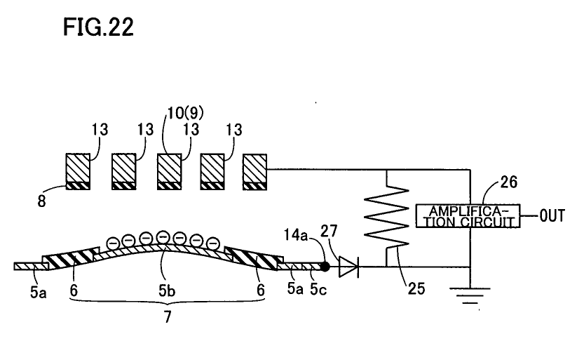

When the polysilicon layer 5b storing the negative charges and causing potential difference between the same and the back plate 10 is sonically vibrated to reduce the distance between the same and the back plate 10 as shown in FIG. 22, the capacitance between the polysilicon layer 5b and the back plate 10 changes to change the potential of the back plate 10 with respect to the ground potential. The amplification circuit 26 amplifies the potential change of the back plate 10 with respect to the ground potential and outputs the same as an electric signal corresponding to sound. The capacitance between the power generation film 6 constituted of the piezoelectric substance and the back plate 10 is negligibly small as compared with that between the polysilicon layer 5b and the back plate 10, whereby potential change of the back plate 10 provided on the region opposed to the power generation film 6 is also negligibly small. Therefore, the microphone senses sound substantially on the basis of change of the capacitance between the polysilicon layer 5b and the back plate 10.

According to this embodiment, as hereinabove described, the diaphragm 7 is provided with the vibratory polysilicon layer 5b capable of storing charges and the power generation film 6 capable of generating power upon vibration with the polysilicon layer 5b so that the power generation film 6 constituted of the piezoelectric substance is also vibrated when the polysilicon layer 5b is sonically vibrated, whereby the polysilicon layer 5b stores charges generated by the power generation film 6 to cause potential difference between the back plate 10 and the diaphragm 7. When the diaphragm 7 is vibrated in the state causing the potential difference between the same and the back plate 10, the distance between the back plate 10 and the diaphragm 7 changes to change the capacitance of a capacitor formed by the back plate 10 and the diaphragm 7 as well as the potential of the back plate 10. The amplification circuit 26 amplifies this potential change and outputs the same as an electric signal, so that the microphone can output sound with an electrical signal. According to this embodiment, further, the power generation film 6 constituted of the piezoelectric substance is so vibrated that the polysilicon layer 5b can store charges, whereby the microphone requires no booster circuit or the like for applying a voltage between the diaphragm 7 and the back plate 10. Thus, a structure related to control including the amplification circuit 26 around the diaphragm 7 etc. can be so downsized as to downsize the microphone. In addition, the power generation film 6 repetitively generates power by vibration, whereby the polysilicon layer 5b can store a large quantity of charges. Thus, large potential difference can be caused between the back plate 10 and the diaphragm 7 including the polysilicon layer 5b, whereby potential change corresponding to change of the capacitance of the capacitor formed by the back plate 10 and the diaphragm 7 can be increased. Thus, the extracted electric signal can be intensified. Consequently, sensitivity of the microphone can be improved without increasing the size of the diaphragm 7. According to this embodiment, therefore, the microphone can be improved in sensitivity and downsized due to the diaphragm 7.

The diaphragm 7 is formed by the power generation film 6 constituted of the piezoelectric substance (PbTiO₃ (Curie temperature: about 490° C.), for example) having higher heat resistance as compared with an electret film formed by an organic film and the polysilicon layer 5b, whereby heat resistance of the diaphragm 7 can be improved as compared with a diaphragm formed by an electret film. Thus, the power generation film 6 and the polysilicon layer 5b can be manufactured through a semiconductor fabrication process, whereby the diaphragm 7 can be downsized. Further, soldering can be automatically performed due to the improved heat resistance.

According to this embodiment, the diode 27 is so electrically connected to the power generation film 6 that the flow of charges generated by the power generation film 6 can be unidirectionally fixed from the power generation film 6 toward the polysilicon layer 5b and outflow of the charges stored in the polysilicon layer 5b can be suppressed, whereby the polysilicon layer 5b hardly loses the charges supplied from the power generation film 6. Thus, the polysilicon layer 5b can efficiently store charges.

According to this embodiment, the power generation film 6 is arranged on the outer periphery of the polysilicon layer 5b, whereby vibrational performance of a maximumly vibrated portion of the circular polysilicon layer 5b can be ensured. Further, the power generation film 6 is so formed as to enclose the polysilicon layer 5b, thereby supplying charges from the overall outer periphery of the polysilicon layer 5b. Thus, the power generation film 6 can supply a larger quantity of charges to the polysilicon layer 5b. In the fabrication process, the power generation film 6 constituted of the piezoelectric substance is so polarized as to generate positive charges on the outer periphery of the power generation film 6 and to generate negative charges on the inner periphery of the power generation film 6, on which the polysilicon layer 5b is located. Thus, external negative charges are attracted by the positive charges generated on the outer periphery of the power generation film 6, to flow into the microphone. These negative charges flow from the outer periphery toward the inner periphery of the power generation film 6. Consequently, the microphone can unidirectionally fix the flow of charges generated by the power generation film 6, thereby efficiently supplying charges to the polysilicon layer 5b.

Although the present invention has been described and illustrated in detail, it is clearly understood that the same is by way of illustration and example only and is not to be taken by way of limitation, the spirit and scope of the present invention being limited only by the terms of the appended claims.

For example, while the present invention is applied to the microphone which is a kind of sonic sensor in the aforementioned embodiment, the present invention is not restricted to this but is also applicable to another sonic sensor other than the microphone or a speaker.

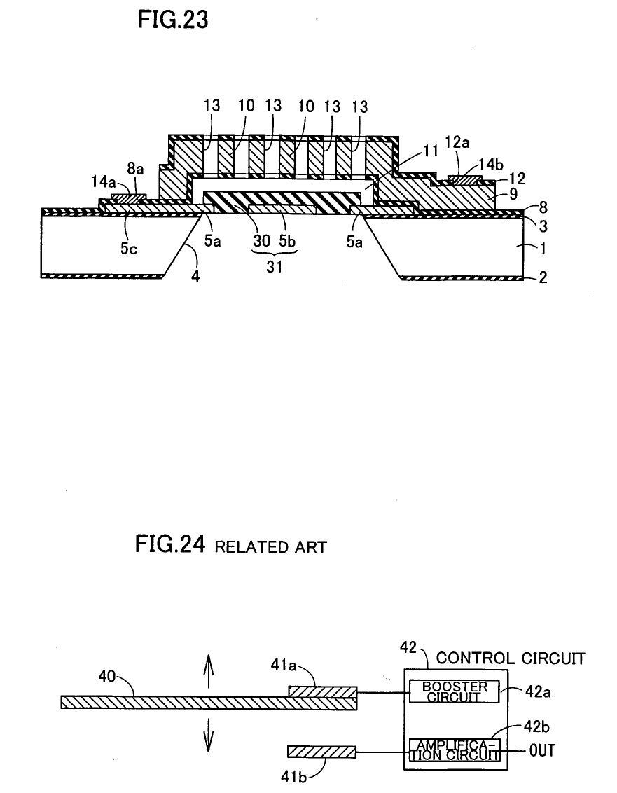

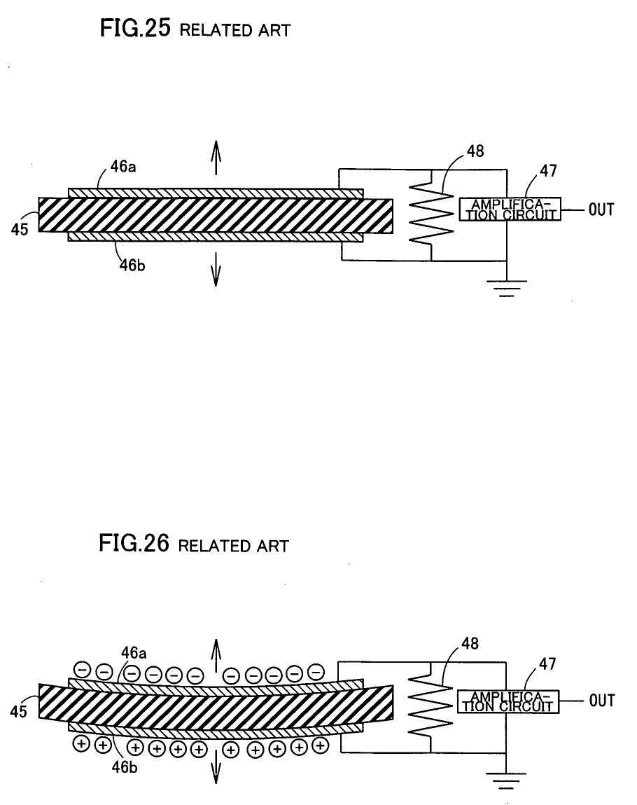

While the power generation film 6 and the polysilicon layer 5b partially overlap with each other in the aforementioned embodiment, the present invention is not restricted to this but a power generation member 30 may alternatively be so formed as to cover the overall surface of a polysilicon layer 5b included in a diaphragm 31 as in a modification of the embodiment of the present invention shown in FIG. 23.

While the piezoelectric substance constituting the power generation film 6 is prepared from PbTiO₃ in the aforementioned embodiment, the present invention is not restricted to this but a single-crystalline substance such as quartz, LiNbO₃, LiTaO₃ or KNbO₃, a thin film of ZnO or AlN, a sintered body of polarized PZT or a piezoelectric polymer membrane of polyvinylidene fluoride (PVDF) or the like may alternatively be employed for constituting the power generation film 6.

While the power generation film 6 is so polarized that positive charges concentrate on the outer periphery of the power generation film 6 and negative charges concentrate on the inner periphery thereof in the aforementioned embodiment, the present invention is not restricted to this but the power generation film 6 may alternatively be so polarized that negative charges concentrate on the outer periphery of the power generation film 6 and positive charges concentrate on the inner periphery thereof. In this case, the diode 27 must be arranged reversely to the arrangement in the aforementioned embodiment. In this case, further, negative charges concentrate on the outer periphery of the power generation film and positive charges concentrate on the inner periphery thereof upon vibration of the power generation film, whereby positive charges are attracted toward the polysilicon layer provided on the outer periphery of the power generation film through the diode. The potential of the polysilicon layer provided on the outer periphery of the power generation film is increased due to these positive charges, whereby negative charges flow out from the polysilicon layer provided on the inner periphery of the power generation film. Consequently, the potential of the polysilicon layer provided on the inner periphery of the power generation film is increased to cause potential difference between the same and the back plate.

While the power generation film 6 is so formed as to enclose the outer periphery of the polysilicon layer 5b for storing charges in the aforementioned embodiment, the present invention is not restricted to this but the power generation film 6 may alternatively be so formed as to partially support the outer periphery of the polysilicon layer 5b for storing charges.

While the diode 27 is formed by a Schottky diode or a p-n junction diode in the aforementioned embodiment, the present invention is not restricted to this but a diode prepared by forming an insulating film between a p region and an electrode of a p-n junction diode may alternatively be employed as a rectifier. When this diode is employed as the rectifier, outflow of stored charges can be further suppressed.

What is claimed is:

1. A sonic sensor comprising:
an electrode plate; and
a diaphragm including a charge storage member opposed to said electrode plate at a prescribed distance and provided in a vibratory manner and a power generation member constituted of a piezoelectric substance capable of generating power upon vibration with said charge storage member, wherein
said charge storage member is so formed as to store charges supplied by said power generation member,
for converting sound to an electrical signal on the basis of change in the capacitance between said diaphragm and said electrode plate.

2. The sonic sensor according to claim 1, wherein
a rectifier suppressing outflow of charges is electrically connected to said power generation member.

3. The sonic sensor according to claim 1, wherein
said power generation member constituted of said piezoelectric substance is arranged on the outer periphery of said charge storage member.

4. The sonic sensor according to claim 3, wherein
said power generation member constituted of said piezoelectric substance includes a power generation film constituted of said piezoelectric substance, and
is so formed as to generate either positive charges or negative charges on the outer periphery of said power generation film in plan view, and
to generate either negative charges or positive charges on the inner periphery of said power generation film, on which said charge storage member is located, in plan view.

5. The sonic sensor according to claim 4, wherein
said power generation film constituted of said piezoelectric substance is so polarized as to generate positive charges on the outer periphery of said power generation film and to generate negative charges on the inner periphery of said power generation film.

6. The sonic sensor according to claim 3, wherein
said power generation member constituted of said piezoelectric substance is so formed as to enclose the outer periphery of said charge storage member in plan view.

7. The sonic sensor according to claim 6, wherein
said charge storage member is circularly formed in plan view, and
said power generation member is so annularly formed as to enclose said circular charge storage member.

8. The sonic sensor according to claim 1, wherein
said charge storage member includes a conductive semiconductor film.

9. The sonic sensor according to claim 1, wherein
said charge storage member and said power generation member are so formed as to at least partially overlap with each other.

10. A diaphragm comprising:
a charge storage member opposed to an electrode plate at a prescribed distance and provided in a vibratory manner; and
a power generation member constituted of a piezoelectric substance capable of generating power upon vibration with said charge storage member, wherein
said charge storage member is so formed as to store charges supplied by said power generation member.

11. The diaphragm according to claim 10, wherein
a rectifier suppressing outflow of charges is electrically connected to said power generation member.

12. The diaphragm according to claim 10, wherein
said power generation member constituted of said piezoelectric substance is arranged on the outer periphery of said charge storage member.

13. The diaphragm according to claim 12, wherein
said power generation member constituted of said piezoelectric substance includes a power generation film constituted of said piezoelectric substance, and
is so formed as to generate either positive charges or negative charges on the outer periphery of said power generation film in plan view, and
to generates either negative charges or positive charges on the inner periphery of said power generation film, on which said charge storage member is located, in plan view.

14. The diaphragm according to claim 13, wherein
said power generation film constituted of said piezoelectric substance is so polarized as to generate positive charges on the outer periphery of said power generation film and to generate negative charges on the inner periphery of said power generation film.

15. The diaphragm according to claim 12, wherein
said power generation member constituted of said piezoelectric substance is so formed as to enclose the outer periphery of said charge storage member in plan view.

16. The diaphragm according to claim 15, wherein
said charge storage member is circularly formed in plan view, and
said power generation member is so annularly formed as to enclose said circular charge storage member.

17. The diaphragm according to claim 10, wherein
said charge storage member includes a conductive semiconductor film.

18. The diaphragm according to claim 10, wherein
said charge storage member and said power generation member are so formed as to at least partially overlap with each other.

19. The diaphragm according to claim 10, wherein
said electrode plate includes a plurality of sonic holes,
so that said diaphragm is applied to an audio.
